(19) United States
(12) Patent Application Publication
(10) Pub. No.: US 2025/0390024 A1
(43) Pub. Date: Dec. 25, 2025

(54) ADAPTIVE OPTICAL MODULE FOR A MICROLITHOGRAPHIC PROJECTION EXPOSURE APPARATUS

(71) Applicant: Carl Zeiss SMT GmbH, Oberkochen (DE)

(72) Inventors: Matthias MANGER, Aalen (DE); Markus RAAB, Schillingsfuerst (DE); Stefan BAUEREGGER, Dillingen a. d. Donau (DE)

(21) Appl. No.: 19/304,878

(22) Filed: Aug. 20, 2025

Related U.S. Application Data
(63) Continuation of application No. PCT/EP2024/055314, filed on Mar. 1, 2024.

(30) Foreign Application Priority Data
Mar. 7, 2023 (DE) 10 2023 202 040.8

(51) Int. Cl. G03F 7/00

(52) U.S. Cl. CPC G03F 7/70266; G03F 7/7085

(57) ABSTRACT

An adaptive optical module for a microlithographic projection exposure apparatus comprises at least one actuator for modifying an optical surface of the optical module. The actuator comprises a dielectric medium that is deformable via an electric field and electrodes for creating the electric field in the dielectric medium by applying a working voltage. Furthermore, the adaptive optical module comprises a measuring device configured to measure an electric charge located on the electrodes when the working voltage is applied, and a processing device configured to use the charge measurement to determine a quantity relating to a displacement of the actuator. The measuring device comprises a measuring capacitor and a voltage measuring unit and is configured to determine the electric charge on the electrodes by way of a voltage measurement. The voltage measuring unit is configured to perform the voltage measurement at the measuring capacitor.

### CROSS-REFERENCE TO RELATED APPLICATIONS

The present application is a continuation of, and claims benefit under 35 USC 120 to, international application No. PCT/EP2024/055314, filed Mar. 1, 2024, which claims benefit under 35 USC 119 of German Application No. 10 2023 202 040.8, filed Mar. 7, 2023. The entire disclosure of each of these applications is incorporated by reference herein.

### FIELD

The disclosure relates to an adaptive optical module for a microlithographic projection exposure apparatus having at least one actuator, a microlithographic projection exposure apparatus having such an adaptive optical module, and a method for determining a displacement of an actuator of an adaptive optical module of a microlithographic projection exposure apparatus.

### BACKGROUND

A projection lens of a microlithographic projection exposure apparatus with wavefront aberrations that are as small as reasonably possible is often desired to help ensure imaging of the mask structures on the wafer as precisely as reasonably possible. Therefore, projection lenses are often equipped with manipulators that allow the correction of wavefront errors by modifying the state of individual optical elements of the projection lens. Examples of such a change of state comprise a change of pose in one or more of the six rigid-body degrees of freedom of the relevant optical element and a deformation of the optical element.

For the latter change of state, the optical element is usually integrated into an adaptive optical module of the aforementioned type. The latter may comprise one or more piezoelectric or electrostrictive actuators for the purpose of actuating the optical surface. The functionality of such actuators is generally based on the deformation of a dielectric medium by the application of an electric field. To determine the desired change of state, the aberration characteristic of the projection lens is usually measured regularly and, if appropriate, changes in the aberration characteristic between the individual measurements are determined by simulation. Thus, it is possible to take account of e.g. lens or mirror heating effects by calculation.

When using piezoelectric or electrostrictive adaptive optical elements, issues often arise because changes of relevant parameters in the actuator material, for instance on account of temperature variations, ageing, defects, drifts, etc., may lead to significant inaccuracies in the surface shape corrections carried out by the adaptive optical element.

In order to correct or avoid these inaccuracies, DE 10 2020 212 743 A1, for example, proposes the arrangement in the actuator material of a measuring electrode that serves for measuring the temperature and the implementation of corresponding corrections on the basis of the measurement result. However, this is an indirect measurement and often lacks sufficient accuracy in capturing surface shape errors caused by actuator deviations.

### SUMMARY

The disclosure seeks to provide an adaptive optical module and a corresponding method that can, for example, allow a surface shape correction of the adaptive optical element to be implemented with improved accuracy.

In an aspect, the disclosure provides an adaptive optical module for a microlithographic projection exposure apparatus, comprising at least one actuator for modifying an optical surface of the optical module, with the actuator comprising a dielectric medium that is deformable via an electric field and electrodes for creating the electric field in the dielectric medium by applying a working voltage. Furthermore, the adaptive optical module comprises a measuring device that is configured to measure an electric charge located on the electrodes when the working voltage is applied and a processing device that is configured to use the charge measurement to determine a quantity relating to a displacement of the actuator. The measuring device comprises a measuring capacitor and a voltage measuring unit and is configured to determine the electric charge on the electrodes by way of a voltage measurement, with the voltage measuring unit being configured to perform the voltage measurement at the measuring capacitor.

The disclosure can allow the determination of a displacement of the actuator at at least one operating point on the basis of an electrical measurement on the electrodes. In comparison with an interferometric measurement of the surface shape on the basis of the working voltage, for example, the measurement according to the disclosure on the electrodes can be carried out with a high repetition rate, optionally even during the exposure operation of a microlithographic projection exposure apparatus.

According to an embodiment, the processing device is configured to determine a displacement of the actuator on the basis of the measured charge. This means that the quantity relating to the displacement of the actuator is the displacement of the actuator.

According to an embodiment, the processing device comprises a feedback circuit that is configured to keep a measured quantity for the electric charge determined during the charge measurement at a target value. In this case, the quantity relating to the displacement of the actuator is e.g. a manipulated variable or correction variable for a voltage generator that sets the working voltage.

According to an embodiment, the measuring device comprises an ohmic resistor that is connected in parallel with the electrodes. The ohmic resistor serves as a shunt resistor for minimizing the effect of a possible parasitic conductivity in the actuator on the charge measurement. The shunt resistor is configured such that its conductivity is at least one order of magnitude greater than the conductivity of the actuator. This means that the resistance of the shunt resistor is at least one order of magnitude smaller than the resistance of the actuator. Hence, the overall resistance value of the arrangement comprising the actuator and the shunt resistor corresponds with a relatively high degree of accuracy to the resistance value of the shunt resistor. Hence, when determining the charge on the electrodes, the influence of the resistance can be taken into account with great accuracy without accurate knowledge of the possibly varying parasitic conductivity. Knowledge of the overall resistance can be desirable in order to be able to accurately define the frequency range of the working voltage suitable for charge measurement.

According to an embodiment, the measuring device comprises a further ohmic resistor that is connected in parallel with the measuring capacitor. The further ohmic resistance makes it possible to precisely define or set the frequency range of the working voltage suitable for charge measurement, and so the measurement is possible at the desired control dynamics of the actuator.

According to an embodiment, a capacitance of the measuring capacitor is at least one order of magnitude, for example at least two orders of magnitude, greater than a capacitance of the actuator.

According to an embodiment, the measuring device comprises a Sawyer-Tower circuit

According to an the disclosure provides an adaptive optical module for a microlithographic projection exposure apparatus comprising at least one actuator for modifying an optical surface of the optical module, with the actuator comprising a dielectric medium that is deformable via an electric field and electrodes for creating the electric field in the dielectric medium by applying a working voltage. Furthermore, the adaptive optical module comprises a measuring device that is configured to measure an electric charge located on the electrodes when the working voltage is applied and a processing device that is configured to use the charge measurement to determine a quantity relating to a displacement of the actuator. The measuring device comprises a measuring capacitor and is configured to determine the electric charge on the electrodes by way of a voltage measurement. Furthermore, the measuring device comprises an operational amplifier and a voltage measuring unit that is configured to perform the voltage measurement at the output of the operational amplifier.

According to an embodiment, the processing device is configured to determine a displacement of the actuator on the basis of the measured charge. This means that the quantity relating to the displacement of the actuator is the displacement of the actuator.

According to an embodiment, the processing device comprises a feedback circuit that is configured to keep a measured quantity for the electric charge determined during the charge measurement at a target value. In this case, the quantity relating to the displacement of the actuator is e.g. a manipulated variable or correction variable for a voltage generator that sets the working voltage.

In an aspect, the disclosure provides an adaptive optical module for a microlithographic projection exposure apparatus comprising at least one actuator for modifying an optical surface of the optical module, with the actuator comprising a dielectric medium that is deformable via an electric field and electrodes for creating the electric field in the dielectric medium by applying a working voltage. Furthermore, the adaptive optical module comprises a measuring device that is configured to measure an electric charge located on the electrodes when the working voltage is applied and a processing device that is configured to use the charge measurement to determine a quantity relating to a displacement of the actuator. The measuring device comprises a current intensity measuring module for measuring a current intensity of a current flowing to the electrodes due to the application of the working voltage and a summation module for determining the electric charge on the electrodes by summing the current intensities measured at different times. According to an embodiment variant, the current intensities measured at different times are summed by integrating a time-dependent current intensity over time.

According to an embodiment, the current intensity measuring module comprises a transimpedance amplifier.

According to an embodiment, the processing device is configured to determine a displacement of the actuator on the basis of the measured charge. This means that the quantity relating to the displacement of the actuator is the displacement of the actuator.

According to an embodiment, the processing device comprises a feedback circuit that is configured to keep a measured quantity for the electric charge determined during the charge measurement at a target value. In this case, the quantity relating to the displacement of the actuator is e.g. a manipulated variable or correction variable for a voltage generator that sets the working voltage.

In an aspect, the disclosure provides an adaptive optical module for a microlithographic projection exposure apparatus comprising at least one actuator for modifying an optical surface of the optical module, with the actuator comprising a dielectric medium that is deformable via an electric field and electrodes for creating the electric field in the dielectric medium by applying a working voltage. Furthermore, the adaptive optical module comprises a measuring device that is configured to measure an electric charge located on the electrodes when the working voltage is applied and a processing device that is configured to use the charge measurement to determine a quantity relating to a displacement of the actuator. The measuring device comprises a current intensity measuring module for measuring a current intensity of a current flowing to the electrodes due to the application of the working voltage and a summation module for determining the electric charge on the electrodes by summing current intensities measured at different times, wherein the current intensity measuring module comprises a shunt resistor and a voltmeter for measuring the voltage drop across the shunt resistor. A shunt resistor is understood to mean an electrical measuring resistor that is inserted into a current-carrying line connected to one of the electrodes. The voltmeter is arranged parallel to the shunt resistor, wherein the shunt resistance is low resistance in comparison with the electrical resistance of the voltmeter. A typical internal resistance of the voltmeter is in the range of 1 to 20 MΩ.

According to an embodiment, the voltmeter comprises a voltage amplifier, for example an inverting amplifier.

According to an embodiment, the processing device is configured to determine a displacement of the actuator on the basis of the measured charge. This means that the quantity relating to the displacement of the actuator is the displacement of the actuator.

According to an embodiment, the processing device comprises a feedback circuit that is configured to keep a measured quantity for the electric charge determined during the charge measurement at a target value. In this case, the quantity relating to the displacement of the actuator is e.g. a manipulated variable or correction variable for a voltage generator that sets the working voltage.

In an aspect, the disclosure provides a microlithographic projection exposure apparatus having an adaptive optical module according the disclosure.

In an aspect, the disclosure provides a method of determining a displacement of an actuator of an adaptive optical module for a microlithographic projection exposure apparatus. The actuator is configured to modify an optical surface of the optical module and comprises a dielectric medium that is deformable via an electric field and electrodes. The method comprises applying a working voltage to the electrodes in order to generate an electric field in the dielectric medium, measuring an electric charge located on the electrodes when the working voltage is applied, and using the charge measurement to determine a quantity relating to the displacement of the actuator.

The features specified with respect to the aforementioned aspects according to the disclosure, embodiments, exemplary embodiments or embodiment variants, etc. of the adaptive optical module according to the disclosure can be correspondingly applied to the method according to the disclosure, and vice versa. These and other features of the embodiments according to the disclosure will be explained in the description of the figures and in the claims. The individual features may be implemented, either separately or in combination, as embodiments of the disclosure. Furthermore, they may describe embodiments that are independently protectable and protection for which is claimed only during or after pendency of the application, as the case may be.

### BRIEF DESCRIPTION OF THE DRAWINGS

Various features and embodiments of the disclosure are illustrated with reference to the attached schematic drawings, in which:

FIG. 1 shows an embodiment of a microlithographic projection exposure apparatus having an adaptive optical module;

FIG. 2 shows an embodiment of the adaptive optical element in an initial state and in a corrected state;

FIG. 3 shows an embodiment of the adaptive optical element in an initial state and in a corrected state;

FIG. 4 shows a section of an embodiment of the adaptive optical module according to FIG. 2 with an embodiment of a measuring device for measuring an electric charge on electrodes of the adaptive optical module and an evaluation device for determining a displacement of an actuator of the adaptive optical module;

FIG. 5 shows diagrams for illustrating a suitable frequency range for operating the adaptive optical module according to FIG. 4;

FIG. 6 shows a section of an embodiment of the adaptive optical module according to FIG. 2 with an embodiment of a measuring device for measuring an electric charge on electrodes of the adaptive optical module and an evaluation device for determining a displacement of an actuator of the adaptive optical module;

FIG. 7 shows a section of an embodiment of the adaptive optical module according to FIG. 2 with an embodiment of a measuring device for measuring an electric charge on electrodes of the adaptive optical module and an evaluation device for determining a displacement of an actuator of the adaptive optical module;

FIG. 8 shows a section of an embodiment of the adaptive optical module according to FIG. 2 with an embodiment of a measuring device for measuring an electric charge on electrodes of the adaptive optical module and an evaluation device for determining a displacement of an actuator of the adaptive optical module;

FIG. 9 shows an embodiment of an optional voltage amplifier used in the optical module according to FIG. 2,

FIG. 10 shows a section of an embodiment of the adaptive optical module according to FIG. 2 with an embodiment of a measuring device for measuring an electric charge on electrodes of the adaptive optical module and a feedback circuit for closed-loop control of a measured quantity determined during the charge measurement; and

FIG. 11 shows an embodiment of a microlithographic projection exposure apparatus comprising an adaptive optical module.

### DETAILED DESCRIPTION OF EXEMPLARY EMBODIMENTS ACCORDING TO THE DISCLOSURE

In the exemplary embodiments or embodiments or variant embodiments described below, elements that are functionally or structurally similar to one another are provided with the same or similar reference signs as far as possible. Therefore, for understanding the features of the individual elements of a specific exemplary embodiment, reference should be made to the description of other exemplary embodiments or the general description of the disclosure.

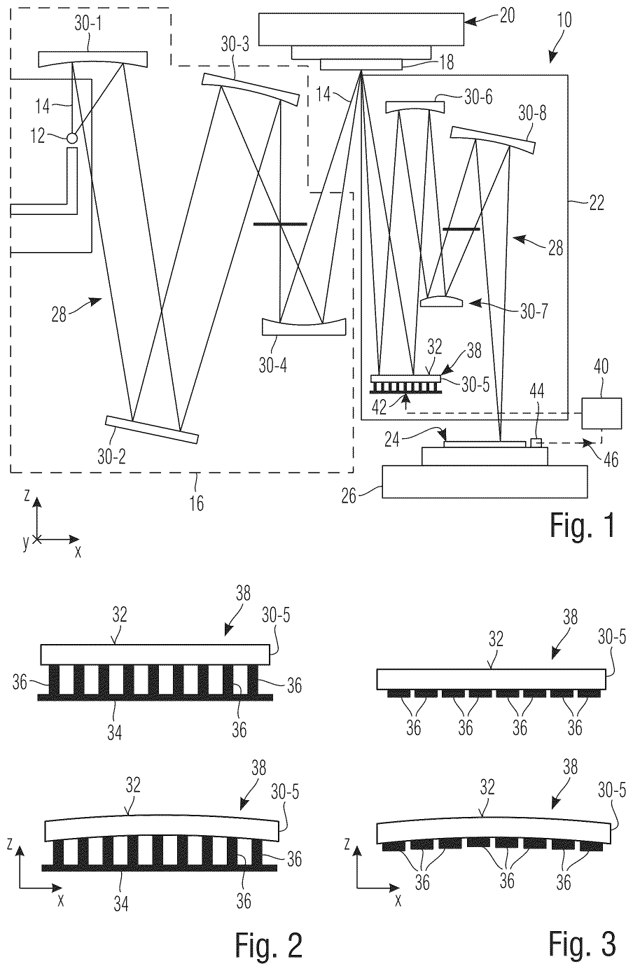

In order to facilitate the description, a Cartesian xyz-coordinate system is indicated in the drawing, from which system the respective positional relationship of the components illustrated in the figures is evident. In FIG. 1, the y-direction runs perpendicularly to the plane of the drawing into the plane, the x-direction runs toward the right, and the z-direction runs upward.

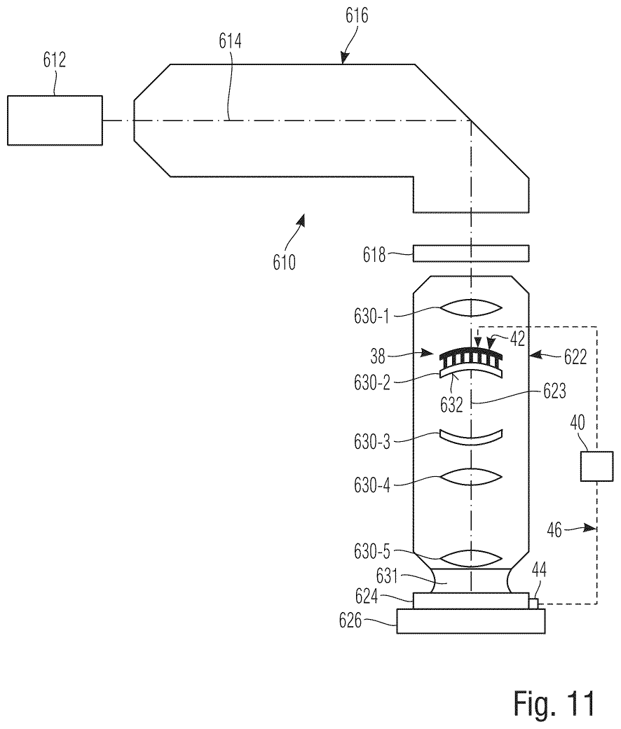

FIG. 1 shows an embodiment according to the disclosure of a microlithographic projection exposure apparatus 10. The present embodiment is designed for operation in the EUV wavelength range, i.e. with electromagnetic radiation at a wavelength of shorter than 100 nm, for example a wavelength of approximately 13.5 nm or approximately 6.8 nm. All optical elements are embodied as mirrors as a result of this operating wavelength. However, the disclosure is not restricted to projection exposure apparatuses in the EUV wavelength range. Further embodiments according to the disclosure are for example designed for operating wavelengths in the UV range, such as 365 nm, 248 nm or 193 nm. In that case, at least some of the optical elements are configured as conventional transmission lens elements, as illustrated by way of example in FIG. 11 described below.

The projection exposure apparatus 10 according to FIG. 1 comprises an exposure radiation source 12 for creating exposure radiation 14. In the present case, the exposure radiation source 12 is embodied as an EUV source and may for example comprise a plasma radiation source. The exposure radiation 14 initially passes through an illumination optics unit 16 and is thereby steered onto a mask 18.

The mask 18 comprises mask structures, which are imaged onto a substrate 24 in the form of a wafer during the exposure operation of the projection exposure apparatus 10, and is displaceably mounted on a mask displacement stage 20. The substrate 24 is displaceably mounted on a substrate displacement stage 26. As illustrated in FIG. 1, the mask 18 may be embodied as a reflection mask, or it may also be configured as a transmission mask in an alternative, especially for UV lithography. In the embodiment according to FIG. 1, the exposure radiation 14 is reflected off the mask 18 and thereupon passes through a projection lens 22 that is configured to image the mask structures onto the substrate 24. The substrate 24 is displaceably mounted on a substrate displacement stage 26. The projection exposure apparatus 10 may be embodied as a so-called scanner or a so-called stepper. The exposure radiation 14 is guided within the illumination optics unit 16 and the projection lens 22 via a multiplicity of optical elements, presently in the form of mirrors.

In the embodiment illustrated, the illumination optics unit 16 comprises four optical elements in the form of mirror elements 30-1, 30-2, 30-3 and 30-4. The projection lens 22 also comprises four optical elements in the form of mirror elements 30-5, 30-6, 30-7 and 30-8. The mirror elements 30-1 to 30-8 are arranged in an exposure beam path 28 of the projection exposure apparatus 10 for the purpose of guiding the exposure radiation 14.

In the embodiment shown, the mirror element 30-5 is part of an adaptive optical module 38, which may also be referred to as an adaptive optical element. In the adaptive optical module 30-5, the optical surface of the mirror element 30-5 serves as active optical surface 32 whose shape can be actively modified in order to correct for local shape errors. In further embodiments, a different mirror element or a plurality of the mirror elements 30-1, 30-2, 30-3, 30-4, 30-5, 30-6, 30-7 and 30-8 may also each be configured as part of an adaptive optical module.

Furthermore, one or more of the mirror elements 30-1, 30-2, 30-3, 30-4, 30-6, 30-7 and 30-8 or the adaptive optical module 38 of the projection exposure apparatus 10 may be movably mounted. To this end, a respective rigid body manipulator is assigned to each of the movably mounted mirror elements. For example, the rigid body manipulators each enable a tilt and/or a displacement of the assigned mirror elements substantially parallel to the plane in which the respective reflective surface of the optical elements is located. Hence, the position of one or more of the mirror elements may be changed for the purpose of correcting imaging aberrations of the projection exposure apparatus 10.

According to an embodiment, the projection exposure apparatus 10 comprises a control device 40 for creating control signals 42 for the manipulation units provided, such as the aforementioned rigid body manipulators, of one or more adaptive optical modules and/or optional further manipulators. In FIG. 1, the transmission of a control signal 42 to the adaptive optical module 38 is illustrated in exemplary fashion. According to an embodiment for correcting aberrations of the projection lens 22, the control device 40 uses a feedforward control algorithm to determine the control signals 42 on the basis of wavefront deviations 46 of the projection lens 22 as measured via a wavefront measuring device 44.

An embodiment of the adaptive optical module 38 is illustrated in FIG. 2. The illustration in the upper section of FIG. 2 shows the adaptive optical module 38 in an initial state in which the shape of the optical surface 32 has an initial shape, a plane shape in this case. The illustration in the lower section of FIG. 2 shows the adaptive optical module 38 in a corrected state in which the shape of the optical surface 32 has a modified shape, a convexly arched shape in this case.

The adaptive optical module 38 comprises a support element 34 in the form of a back plate and the mirror element 30-5, the top side of which forms the active optical surface 32 and serves to reflect the exposure radiation 14. A multiplicity of actuators 36, which are also referred to as manipulators, are arranged along the underside of the mirror element 30-5. In this case, these can be positioned both in the x-direction and in the y-direction, i.e. in a two-dimensional arrangement, along the underside of the mirror element 30-5. The actuators 36, only a few of which have been provided with a reference sign in FIG. 2 for reasons of clarity, connect the support element 34 to the mirror element 38. The actuators 36 are configured to change their extent along their longitudinal direction in the case of actuation. In the embodiment according to FIG. 2, the actuators 36 are actuatable across or perpendicular to the optical surface 32. The actuators 36 are each driven individually in this case and can therefore be actuated independently of one another. The adaptive optical module 38 may have more or fewer actuators 36 than the number shown in FIG. 2. In the corrected state shown in the lower section of FIG. 2, centrally arranged actuators 36 have an increased length on account of their actuation, and so the convexly arched shape arises for the optical surface 32.

FIG. 3 illustrates an embodiment of the adaptive optical module 38. In a manner analogous to FIG. 2, the illustration in the upper section of FIG. 3 shows the adaptive optical module 38 in an initial state in which the shape of the optical surface 32 has a plane shape as initial shape. The illustration in the lower section of FIG. 3 shows the adaptive optical module 38 in a corrected state in which the shape of the optical surface 32 has a convexly arched and hence a changed shape.

The adaptive optical module 38 according to FIG. 3 differs from the embodiment according to FIG. 2 to the extent that the actuators 36 are arranged on the underside of the mirror element 30-5 not across but parallel to the optical surface 32, and the actuators 36 are not carried by a rigid support element arranged parallel to the mirror element 30-5. That is to say, the actuators 36 are deformable not across the optical surface 32, as in FIG. 2, but parallel to the optical surface 32. As a result of the strain or contraction of the individual actuators 36 parallel to the surface, a bending moment is introduced into the mirror element 30-5 and leads to deformation of the latter, as illustrated in the lower section of FIG. 3. In an embodiment variant not depicted here, the actuators according to FIG. 3 are embedded in one or more monolithic tiles. These reduce the integration effort involved in manufacturing the adaptive optical module 38.

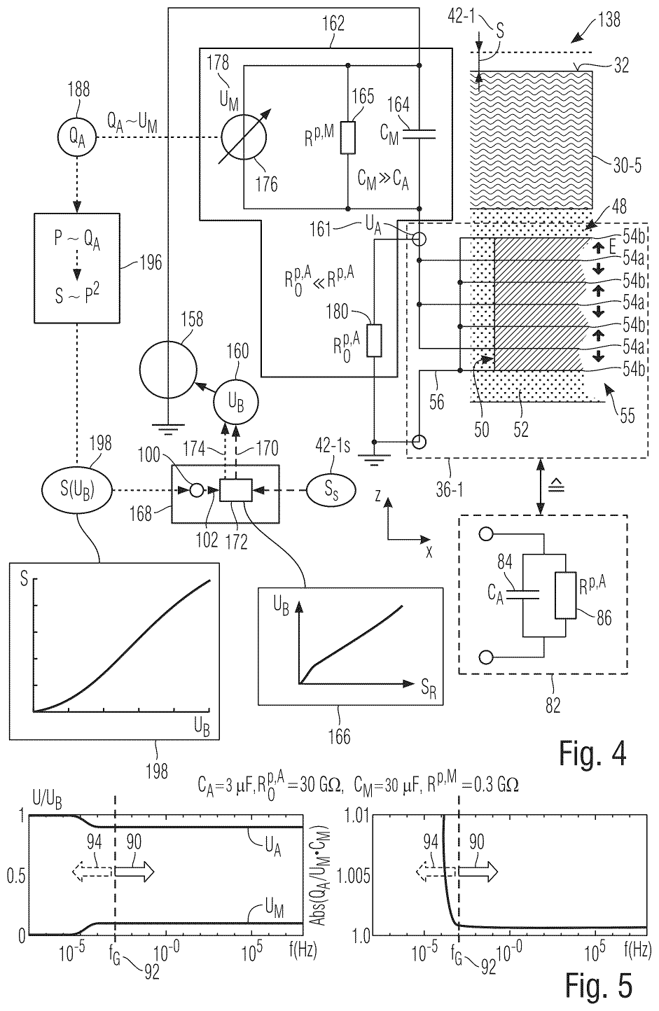

By driving each individual actuator 36, it is possible both in the embodiment according to FIG. 2 and in the embodiment according to FIG. 3 to set profiles of the mirror element 30-5 in a targeted manner and consequently correct the optical system, for example the projection lens 22 or the illumination optics unit 16, of the projection exposure apparatus 10 to the best possible extent. To drive the actuators 36 in this way, the control signal 42 contains target displacements for the various actuators 36. Such a target displacement for one of the actuators 36-1 is indicated in FIG. 4 by the reference sign 42-1S.

FIG. 4 illustrates a section of an embodiment 138 of the adaptive optical module 38 according to FIG. 2 with one of the actuators 36, which is labeled here by reference sign 36-1. As illustrated in exemplary fashion for the actuator 36-1 in FIG. 4, the actuators 36 of the adaptive optical module 138 each comprise a dielectric medium 48 that is deformable by the application of an electric field. This may be a piezoelectric material or an electrostrictive material. The deformation is based on the piezoelectric effect in the case of a piezoelectric material, while it is based on the electrostrictive effect in the case of an electrostrictive material. In this text, the electrostrictive effect is understood to mean the component of a deformation of a dielectric medium based on an applied electric field, in which the deformation is independent of the direction of the applied field and, for example, proportional to the square of the electric field. In contrast thereto, the linear response of the deformation to the electric field is referred to as piezoelectric effect.

In the embodiment variant described below, the actuators 36 are embodied as ferroelectric actuators and are based on the electrostrictive effect. These are particularly well suited to correcting the shape of the active optical surface 32 since these have a very small drift and exhibit only a minor hysteresis.

The actuator 36-1 illustrated in FIG. 4 comprises the dielectric medium 48, which was already mentioned above and which rests against the back side of the mirror element 30-5, electrodes 54 and wiring 56 of the electrodes 54. The dielectric medium 48 has an integral embodiment in the form of a ceramic part, with the electrodes 54 being embedded or integrated therein. The integral dielectric medium 48 is a contiguous and seamless monolithic dielectric medium and is created by sintering, for example.

Expressed differently, the electrodes 54 are arranged in an assemblage with the integral dielectric medium 48. The dielectric medium 48 contains the electrodes 54 in the form of an electrode stack, which is also referred to as an electrode assembly 55 hereinafter. In the embodiment shown, the electrode arrangement 55 contains seven plate-like electrodes 54 arranged one above the other. The entire region of the dielectric medium 48 arranged between electrodes 54 is referred to as the active volume 50 of the dielectric medium 48. The region of the dielectric medium 48 arranged outside of the electrode stack is accordingly referred to as inactive volume 52. In the embodiment shown, the inactive volume 52 completely surrounds the active volume 50.

The wiring 56 of the electrodes 54 connects these in alternation to the positive and negative terminals of the voltage generator 158, which generates an operating voltage U_{B} (reference sign 160). In this case, the negative terminal of the voltage generator 158 is connected to ground. The electrodes 54 connected to the positive terminal of the voltage generator 158 are referred to as driving electrodes 54a, while the remaining electrodes are connected to ground just like the negative terminal of the voltage generator 158 and therefore referred to as base electrodes 54b.

A section of a measuring device 162 comprising a measuring capacitor 164 and optionally an ohmic resistor 165 connected in parallel is connected between the positive terminal of the voltage generator 158 and the driving electrodes 54a. In other words, this section of the measuring device 162 is upstream of the actuator 36-1. The voltage present at the electrode assembly 55 of the actuator 36-1 is referred to as actuator voltage U_{A} (reference sign 161) or else working voltage and corresponds to the difference between the operating voltage 160 generated by the voltage generator 158 and a voltage drop across the upstream section of the measuring device 162. According to an alternative embodiment, the section of the measuring device 162 comprising the measuring capacitor 164 and the optional ohmic resistor 165 connected in parallel may be downstream of the actuator 36-1. In other words, in the latter embodiment, the relevant section of the measuring device 162 is connected between the base electrodes 54b and the ground.

The operating voltage 160 is a DC voltage with variable voltage value UBA. The wiring 56 is configured in such a way that the electric field 55 with the field strength E created in each case between two adjacent electrodes 50 alternates on account of the applied operating voltage 160. Since the dielectric medium 48 is an electrostrictive material in the present case, the expansion of the dielectric medium 48 caused by the electric field is independent of the direction of the electric field 55, i.e. the change in the expansion in the z-direction of the layers of the dielectric medium 48 arranged between the electrodes 54 is directed in the same way. At the same time, the dielectric medium contracts in the x-direction and y-direction. Hence, the length expansion of the active volume 50 of the dielectric medium 48 changes in the z-direction when an operating voltage 160 generated by the voltage generator 158 is applied, and there is a corresponding change in the x-direction and y-direction. The absolute value of the change in length expansion depends on the actuator voltage 161 and analogously on the operating voltage 160 generated by the voltage generator 158. The overall change in the length extension of the actuator 36-1 when applying an actuator voltage 161 that differs from 0 V is referred to as displacement S, which is provided with reference sign 42-1 in FIG. 4.

Before the adaptive optical module 138 is put into operation, a reference characteristic 166 between the displacement S and the operating voltage U_{B} is optionally measured in a so-called reference mode. In the reference mode, different values for the operating voltage U_{B}, i.e. different operating points of the operating voltage U_{B}, are set and the corresponding displacement SR of the optical surface 32 of the actuator 36-1 is measured for each of these values via a reference measuring module in the form of an interferometer.

Furthermore, the embodiment of the adaptive optical module 138 illustrated in FIG. 4 comprises a control unit 168 that is assigned to the depicted manipulator 36-1. This control unit 168 may be part of a control module that controls a plurality of manipulators 36 of the adaptive optical module 138. Furthermore, the control unit may either be part of the adaptive optical module 138 or else be arranged outside of the adaptive optical module 138, for example be part of the control device 40 of the projection exposure apparatus 10.

In a control mode 170, the target displacement Ss (reference sign 42-1s), which is contained in the control signal 42 outgoing from the control device 40, is read by the control unit 168 for the manipulator 36-1 shown in FIG. 4. The information flow in the control mode 170 is labelled using dashed lines in FIG. 4. A conversion formula 172 for determining a default for the operating voltage U_{B} from the specified target displacement Ss is stored in the control unit 168. For example, the conversion formula 172 can be formed by a curve of the operating voltage U_{B} as a function of the target displacement Ss. This curve is advantageously determined before the adaptive optical element 138 is put into operation from the reference characteristic 166 that specifies the curve of SR as a function of U_{A} and is determined in the reference mode. Alternatively, the conversion formula 172 may be determined via a calibration mode 174 described in detail below. During operation, the conversion formula 172 is corrected in ongoing fashion, as will be described in detail below.

For the read target displacement Ss, the control device 40 determines a corresponding control value for the operating voltage U_{B} on the basis of the conversion formula 172 and uses this to control the voltage generator 158. A calibration mode 174 for calibrating the conversion formula 172 is applied each time a new operating voltage U_{B} is set via the voltage generator 158, or at certain time intervals. The information flow in calibration mode 174 is shown in FIG. 4 via a dotted line.

To carry out the calibration mode 174, the embodiment of the adaptive optical module 138 illustrated in FIG. 4 comprises the measuring device 162 that is assigned to the depicted actuator 36-1. In addition to the aforementioned measuring capacitor C_{M} (reference sign 164) and the optional ohmic resistance R^{p,M} (reference sign 165) connected in parallel, the measuring device comprises a voltage measuring unit 176 for measuring the voltage U_{M} (reference sign 178) drop across the measuring capacitor 164. The voltage U_{M} corresponds to the difference between the voltages U_{B} and U_{A}. Moreover, the measuring device 162 optionally comprises a further ohmic resistance R₀^{p,A} (reference sign 180), which is connected in parallel with the electrode arrangement 55.

The functionality of the actuator 36-1 surrounded by a dotted frame can be illustrated by the equivalent circuit diagram 82, which is also surrounded by a dotted frame in FIG. 4. This equivalent circuit diagram 82 comprises a capacitor 84 with an actuator capacitance C_{A} and an internal parallel resistor 86 with the resistance value R^{p,A}, which represents a parasitic electrical conductivity of the actuator 36-1.

The arrangement of the measuring capacitor 164 in a series connection with the actuator 36-1 corresponds to a Sawyer-Tower circuit. When operating the actuator 36-1 at the actuator voltage 161 in a suitable frequency range, which is explained in detail below, the voltage U_{M} drop across the measuring capacitor 164 is suitable for determining the electric charge Q_{A} (reference sign 188). The charge Q_{A} corresponds to the charge present on the electrodes 54 of the actuator 36-1, or on the capacitor 84 in the equivalent circuit diagram 81, when the actuator voltage 161 is applied. This measurement is based on the effect that the charge present on the electrodes 54 of actuator 36-1 is “reflected” on the measuring capacitor 164, i.e. the same absolute value of charge is present on the electrodes 54 and on the measuring capacitor 164.

The measurement of the electric charge Q_{A} on the electrodes 54 of the actuator 36-1 is thus carried out in the measuring device 162 according to FIG. 4 by measuring the voltage U_{M} via the voltage measuring unit 176. Since the capacitance C_{M} of the measuring capacitor 164 is known, the charge Q_{M} on the measuring capacitor 164, which corresponds to charge Q_{A} in the appropriate frequency range specified above, arises from the following relationship: Q_{M}=C_{M}·U_{M}. To ensure that the main part of the operating voltage 160 drops across the actuator 36-1 and only a subordinate part of the operating voltage 160 drops across the measuring capacitor 164, the capacitance C_{M} of the measuring capacitor 164 is chosen to be smaller than the capacitance C_{A} of the actuator 36-1 by at least a factor of 5, optionally by one order of magnitude. For example, this ensures that the operating voltage U_{B} remains manageable during actuator operation. According to an exemplary embodiment, C_{A}=3 μF and C_{M}=30 μF.

The aforementioned, suitable frequency range for measuring the charge Q_{A} is denoted by the reference sign 90 and is now described in detail with reference to FIG. 5. The suitable frequency range 90 is the frequency range in which the capacitors of the circuit, i.e. the measuring capacitor 164 and the capacitor 84 of the actuator 36-1 shown in the equivalent circuit diagram 82, dominate when the operating voltage U_{B} is divided into the measuring voltage U_{M} and the actuator voltage U_{A}. As evident from the diagram shown in the left-hand region of FIG. 5, the measuring voltage U_{M} in the suitable frequency range 90 is about 10% of the operating voltage U_{B} and the actuator voltage U_{A} is about 90% in the aforementioned exemplary embodiment, in which C_{A}=3 μF and C_{M}=30 μF. To set the cutoff frequency f_{G} (reference sign 92) between the suitable frequency range 90 and a frequency range 94 that is not suitable for measuring the charge, provision is made for the aforementioned resistors 165 and 180 in the measuring device 162. The resistor

$${R}_{0}^{p , A}$$

(reference sign 180) connected in parallel with the electrodes 54 of the actuator 36-1 is also referred to as a shunt resistor and serves to define the ohmic resistance of the actuator 36-1 more precisely. As mentioned above, the actuator 36-1 has an internal parallel resistance R^{p,A} that is due to a parasitic electrical conductivity of the actuator 36-1. However, the parasitic conductivity is not known accurately. As a result of the parallel arrangement of the resistor

$${R}_{0}^{p , A}$$

with a resistance value that is much greater than the internal parallel resistance R^{p,A}, the overall resistance of the arrangement comprising the actuator 36-1 and the resistor

$${R}_{0}^{p , A}$$

corresponds substantially to the value

$${R}_{0}^{p , A}$$

of the resistor 180, which is known in advance.

The resistance values

$${R}_{0}^{p , A}$$

and R^{p,A} of resistors 180 and 165 are selected such that

$${R}_{0}^{p , A} \cdot {C}_{A} = {R}^{p , M} \cdot {C}_{M} \cdot κ , where 5 \leq κ \leq 20$$

In the present example,

$${R}_{0}^{p , A} = 30$$

GΩ and R^{p,M}=0.3 GΩ. This results in the time constant T=90.000 s (τ=R·C) for the combination of

$${R}_{0}^{p , A}$$

and C_{A}, which corresponds to a cutoff frequency of approximately 10⁻⁵ Hz. For the combination of R^{p,M} and C_{A}, a cutoff frequency of about 10⁻⁴ Hz is obtained.

As evident from the diagram shown in the left-hand section of FIG. 5, a range, in which it is no longer the capacitors of the circuit but the ohmic resistors 165 and 180 that dominate when the operating voltage U_{B} is divided into the measuring voltage U_{M} and the actuator voltage U_{A}, is obtained at frequencies below the cutoff frequency 92 of the arrangement of the actuator 36-1 and the measuring device 162. This range is the aforementioned frequency range 94, which is not suitable for measuring the charge 188. The cutoff frequency 92 in this case is approximately 10⁻³ Hz and hence in the order of magnitude of the cutoff frequencies of the aforementioned RC elements. In the unsuitable frequency range 94, the capacitors 164 and 84 block the current flow, and the resistors 165 and 180 form a voltage divider, and so the operating voltage U_{B} is divided according to the ratio of the resistance values R^{p,M} and

$${R}_{0}^{p , A} ,$$

i.e. U_{M}≈0.01·U_{B} and U_{A}≈0.99. U_{B}.

From the diagram depicted in the right-hand section of FIG. 5, it is evident that, in the appropriate frequency range 90, the ratio of the charge Q_{A} on the actuator 36-1 and the charge on the measuring capacitor 164 (corresponds to the product U_{M}·C_{M}) is equal to 1, and hence Q_{A} can be determined from the measured voltage U_{M} when the value for C_{M}, which is known in advance, is taken into account. In the unsuitable frequency range 94, by contrast, the value for the product U_{M}·C_{M} differs greatly from 1, i.e. Q_{A} can no longer be determined from the measured voltage U_{M}.

The resistance values

$${R}_{0}^{p , A}$$

and R^{p,M} for resistors 180 and 165 are chosen while designing the circuit, with the desired control dynamics of the actuator 36-1 being taken into account. On the basis of the resultant minimum frequency of the operating voltage 160, the resistors 180 and 165 are configured to set the cutoff frequency 92 matched thereto.

The displacement S of the actuator 36-1 is determined in a processing device in the form of an evaluation device 196 from the value of the charge Q_{A} determined by the measuring device 162. To this end, the charge Q_{A} is initially converted into the polarization P on the electrodes 54. The relationship between Q_{A} and P is as follows: Q_{A} (P)=N_{S}·A_{E}·P, where N_{S} is the number of actuator layers present in each case between two opposing electrodes 54a and 54b—in the present case, N_{S}=6—and A_{E} is the respective area of electrodes 54a and 54b. P is therefore proportional to Q_{A}. The constant of proportionality can be determined by a suitable calibration or by model-based calculation.

From the determined polarization P, the evaluation device 196 determines the displacement S. Since the present embodiment relates to an electrostrictive actuator 36-1, the displacement S is proportional to the square of the polarization (S˜P²). The constant of proportionality can be determined by a suitable calibration or by model-based calculation.

The displacement S is determined for different operating voltages U_{B}, and hence the evaluation device 196 determines a dependence S(U_{B}) of the displacement of the actuator 36-1 on the operating voltage U_{B}, the dependence being denoted by reference sign 198. The dependence S(U_{B}) is transmitted to a comparison module 100 of the control unit 168. The latter compares the characteristic specified by dependence 198 with the reference characteristic 166 and brings about a corresponding correction 102 of the conversion formula 172 of the control unit 168 if deviations are found. Alternatively, the control unit 168 calculates the conversion formula 172 directly from the dependence 198. In any case, in the control mode 170, the control unit 168 determines the control value of the operating voltage U_{B} for the voltage generator 158 on the basis of the determined dependence 198.

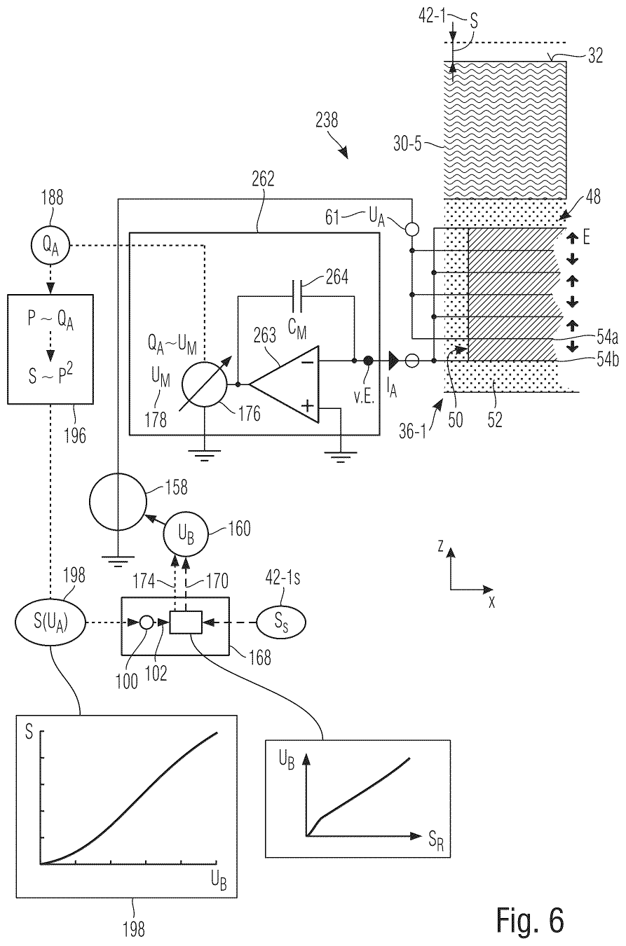

FIG. 6 illustrates an embodiment 238 of the adaptive optical module 38 according to FIG. 2 with one of the actuators 36, which is labeled here by reference sign 36-1. The adaptive optical module 238 according to FIG. 6 differs from the adaptive optical module 138 according to FIG. 4 only in terms of the configuration of the measuring device 162, which in the embodiment according to FIG. 6 is denoted by reference sign 262. In the embodiment according to FIG. 6, the positive terminal of the voltage generator 158 is directly connected to the driving electrodes 54a of the actuator 36-1, and the measuring device 262 is connected downstream of the actuator 36-1, i.e. between the base electrodes 54b and the ground.

The measuring device 262 is configured as an integrator circuit, which comprises an operational amplifier 263, a capacitor C_{M} arranged in the feedback loop of the operational amplifier 263 (reference sign 264) and a voltage measuring unit 176. The base electrodes 54b of the actuator 36-1 are connected to the negative input of the operational amplifier 263, and the ground is connected to the positive input of the operational amplifier 263. The negative input of the operational amplifier 263 is thus connected to ground virtually, i.e. it is at a virtual reference potential or virtual ground (v.E.). Hence, the actuator voltage U_{A} present at the actuator 36-1 corresponds to the operating voltage U_{B}.

The capacitor 264, which may also be referred to as measuring capacitor, is switched between the negative input and the output of the operational amplifier 263. The current intensity I_{A} (reference sign 267) flowing into the actuator 36-1, i.e. onto the base electrodes 54b of the actuator 36-1, due to the applied working voltage U_{A} is integrated over time by the capacitor 264 such that the voltage U_{M} applied to the output of the operational amplifier 263 is proportional to the charge Q_{A} located on the electrodes 54b.

The voltage U_{M} is measured by the voltage measuring unit 176, whereupon the measuring device 262 determines the corresponding charge Q_{A} and transmits the latter to the evaluation device 196.

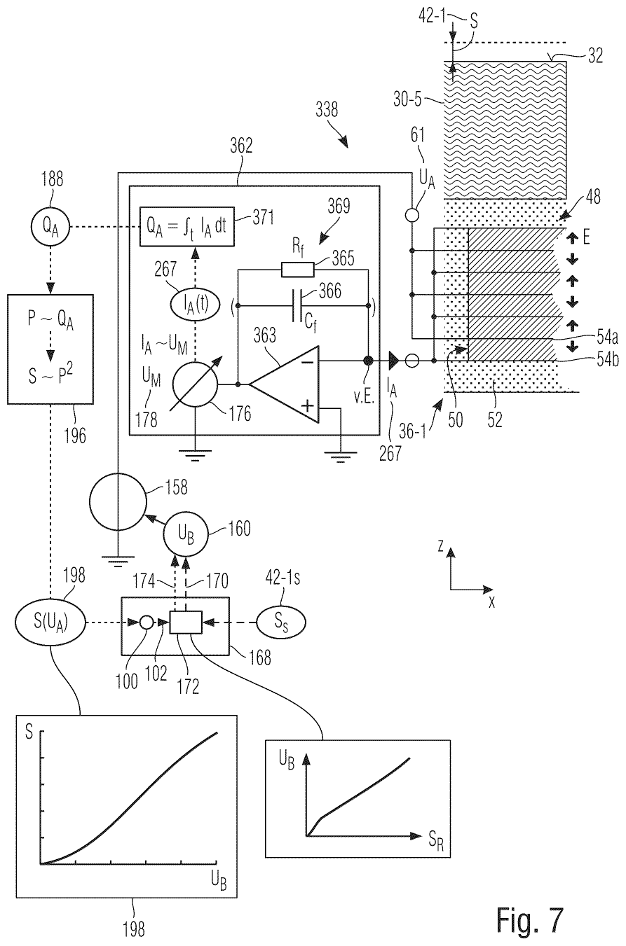

FIG. 7 illustrates an embodiment 338 of the adaptive optical module 38 according to FIG. 2 with one of the actuators 36, which is labeled here by reference sign 36-1. The adaptive optical module 338 according to FIG. 7 differs from the adaptive optical module 238 according to FIG. 6 only in terms of the configuration of the measuring device 262, which in the embodiment according to FIG. 7 is denoted by reference sign 362.

The measuring device 362 comprises a current intensity measuring module 369 in the form of a transimpedance amplifier and a summation module 371. The transimpedance amplifier 369 represents a current intensity-voltage converter and is configured to measure the current intensity I_{A} (reference sign 267) of the current flowing due to the application of the working voltage U_{A} to the base electrodes 54b of the actuator 36-1. To this end, the transimpedance amplifier 369 comprises an operational amplifier 363, a measuring resistor Rf (reference sign 365) arranged in the feedback loop of the operational amplifier 363, optionally a smoothing capacitor 366 for avoiding overshoots, and a voltage measuring unit 176.

The base electrodes 54b of the actuator 36-1 are connected to the negative input of the operational amplifier 363, and the ground is connected to the positive input of the operational amplifier 363. The negative input of the operational amplifier 363 is thus connected to ground virtually, i.e. it is at a virtual reference potential. Hence, the actuator voltage U_{A} present at the actuator 36-1 corresponds to the operating voltage U_{B}. The measuring resistor 365 is connected between the negative input and the output of the operational amplifier 363.

The voltage U_{M} present at the output of the operational amplifier 263 is proportional to the current intensity I_{A}(t) flowing at the time in question. The latter is measured by the voltage measuring unit 176 and transmitted to the summation module 371. The summation module 371 calculates the current intensities I_{A} measured at different times and thus calculates the charge Q_{A} that flowed to the electrodes 54 over a certain period of time. According to an embodiment variant, the summation module 371 determines the charge Q_{A} by integrating the time-dependent current intensity I_{A}(t) over time t: Q_{A}=∫ₜ I_{A} dt. The charge Q_{A} determined in this way is transmitted from the measuring device 362 to the evaluation device 196.

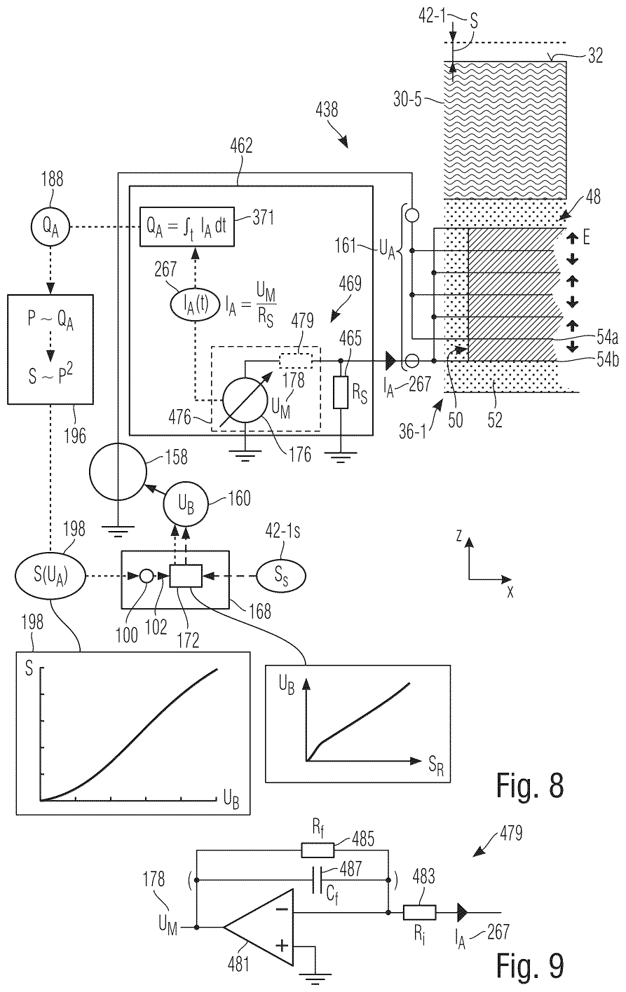

FIG. 8 illustrates an embodiment 438 of the adaptive optical module 38 according to FIG. 2 with one of the actuators 36, which is labeled here by reference sign 36-1. The adaptive optical module 438 according to FIG. 8 differs from the adaptive optical module 338 according to FIG. 7 only in terms of the configuration of the measuring device 362, which in the embodiment according to FIG. 8 is denoted by reference sign 462.

The measuring device 462 according to FIG. 8 differs from the measuring device 362 according to FIG. 7 only in terms of the configuration of the current intensity measuring module 369, which in the embodiment according to FIG. 8 is provided with reference sign 469. The current intensity measuring module 469 comprises a shunt resistor 465, which is connected between a line connected to the base electrodes 54b and a ground. Furthermore, the current intensity measuring module 469 comprises a voltage measuring device 476 for measuring a measuring voltage U_{M} (reference sign 178) drop across the shunt resistor 465. To this end, the voltmeter 476 comprises a voltage measuring unit 176 and optionally a voltage amplifier 479. The operating voltage U_{B} is thus divided into the voltage U_{A} drop across the actuator 36-1 and the voltage U_{M} drop across the shunt resistor 465.

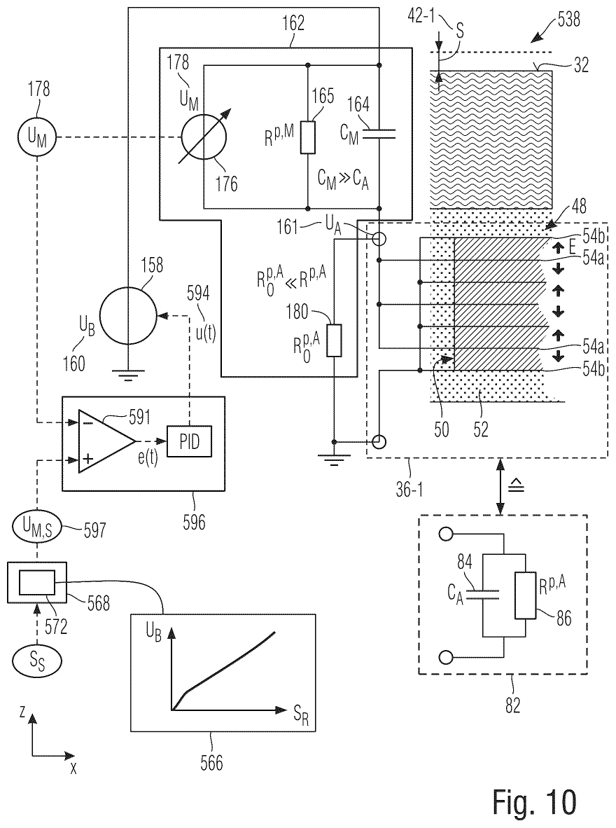

FIG. 9 illustrates an embodiment of the voltage amplifier 479, which is designed as an inverting voltage amplifier. The voltage amplifier 479 comprises an operational amplifier 481, a first resistor Ri (reference sign 483) connected to the negative terminal of the operational amplifier 481, a second resistor Rf (reference sign 485) arranged in the feedback loop of the operational amplifier 481 and optionally a smoothing capacitor 487 for avoiding overshoots.

The measurement voltage U_{M} measured by the voltmeter 476 is proportional to the current intensity I_{A} (reference sign 267) of the current flowing to the base electrodes 54b of the actuator

$$36 - 1 ( {I}_{A} = \frac{{U}_{M}}{{R}_{S}} )$$

due to the working voltage U_{A} present. The current intensity I_{A}(t) arising from the measured measurement voltage U_{M} is transmitted to the summation module 371. The summation module 371 calculates the charge Q_{A} that flowed to the electrodes 54 over a certain period of time, as already described with reference to FIG. 7. The charge Q_{A} determined in this way is transmitted from the measuring device 462 to the evaluation device 196.

FIG. 10 illustrates an embodiment 538 of the adaptive optical module 38 according to FIG. 2 with one of the actuators 36, which is labeled here by reference sign 36-1. The adaptive optical module 438 according to FIG. 10 differs from the adaptive optical module 138 according to FIG. 4 in that it comprises a processing device in the form of a feedback circuit 596. The feedback circuit 596 is configured to keep the measured quantity U_{M}, which is determined during the charge measurement for the electric charge Q_{A} carried out using the measuring device 138, at a target value U_{M,S} (reference sign 597). In contrast with the embodiment according to FIG. 4, the voltage U_{M} measured by the measuring device 162 is not converted into the electric charge Q_{A} but serves directly as a control variable for the feedback circuit 596.

The target value U_{M,S} of the measured quantity U_{M} is determined in a control mode by a control unit 568 from the target displacement Ss provided by the control device 40. This is implemented using a conversion formula 572, which is determined in a manner analogous to the conversion formula 172 that was already explained with reference to FIG. 4. For example, the conversion formula 572 can be determined from a reference characteristic 566, which is determined before the adaptive optical module 538 is put into operation. The reference characteristic 566 specifies the curve SR as a function of U_{A}.

According to an embodiment, the feedback circuit 596 comprises an operational amplifier 591, to whose positive and negative inputs the target value U_{M,S} and the measured voltage U_{M} are applied. Alternatively, the function of the operational amplifier 591 may also be carried out digitally. The difference between U_{M} and U_{M,S} is transmitted as a system deviation e(t) to a controller, a PID controller in this case, which from this determines a manipulated variable u(t) (reference sign 594) and transmits the latter to the voltage generator 158 for appropriate correction of the operating voltage U_{B}. The manipulated variable 594 may also be referred to as correction variable and represents a quantity relating to the displacement 42-1 of the actuator 36-1.

Further embodiments of the adaptive optical module can be configured by integration of a feedback circuit configured in a manner analogous to the feedback circuit 596 according to FIG. 10 into the embodiments 238, 338 and 438 according to FIGS. 6, 7 and 8, respectively.

FIG. 11 shows a schematic view of a projection exposure apparatus 610 configured for operation in the DUV wavelength range and comprising an illumination optics unit in the form of a beam-shaping and illumination system 616 and comprising a projection lens 622. In this case, DUV stands for “deep ultraviolet” and denotes a wavelength of the exposure radiation 614 utilized by the projection exposure apparatus 610 of between 100 nm and 250 nm. The beam-shaping and illumination system 616 and the projection lens 622 can be arranged in a vacuum housing and/or be surrounded by a machine room with corresponding drive apparatuses.

The DUV projection exposure apparatus 610 comprises a DUV exposure radiation source 612. For example, an ArF excimer laser that emits exposure radiation 614 in the DUV range at, for example, approximately 193 nm may be provided to this end.

The beam-shaping and illumination system 616 illustrated in FIG. 11 guides the exposure radiation 614 to a photomask 618. The photomask 618 is embodied as a transmissive optical element and may be arranged outside the systems 616 and 622. The photomask 618 has a structure of which a reduced image is projected onto a substrate 624 in the form of a wafer or the like via the projection lens 622. The substrate 624 is displaceably mounted on a substrate displacement stage 626.

The projection lens 622 comprises a number of optical elements 630 in the form of lens elements and/or mirrors for projecting an image of the photomask 618 onto the substrate 624. In the embodiment illustrated, the optical elements 630 comprise lens elements 630-1, 630-4 and 630-5, the mirror 630-3 and the further mirror 230-2 embodied as an adaptive optical module 38. In this case, individual lens elements and/or mirrors of the projection lens 622 may be arranged symmetrically in relation to an optical axis 623 of the projection lens 622. It should be noted that the number of lens elements and mirrors of the DUV projection exposure apparatus 210 is not restricted to the number shown. More or fewer lens elements and/or mirrors may also be provided. Furthermore, the mirrors are generally curved on their front side for beam shaping.

An air gap between the last lens element 630-5 and the substrate 624 may be replaced by a liquid medium 631 which has a refractive index of >1. The liquid medium 631 may be high-purity water, for example. Such a construction is also referred to as immersion lithography and has an increased photolithographic resolution. The medium 631 may also be referred to as an immersion liquid.

In the exemplary embodiment shown in FIG. 11, the adaptive optical module 38 is embodied in a manner analogous to the adaptive optical module 38 according to FIG. 1, with it naturally comprising a different mirror element to that in FIG. 1. The adaptive optical module 38 is designed such that the shape of the surface 632 of the mirror 630-2 can be actively changed for the purpose of correcting local shape errors. The mirror surface is therefore also referred to as active optical mirror surface 632. In this case, the adaptive optical module 38 according to FIG. 9 may be configured in one of the embodiments as shown in FIGS. 2, 3, 4, 6, 7, 8 and 10. All statements regarding the adaptive optical module 38 given above with reference to FIGS. 1 to 10 may thus be transferred to the adaptive optical module 38 according to FIG. 11.

In a manner analogous to the projection exposure apparatus 10 according to FIG. 1, the adaptive optical module 38 according to FIG. 11 is controlled by control signals 42 which are determined by a control device 40 on the basis of wavefront deviations 46 of the projection lens 622 measured using a wavefront measuring device 44. Without loss of generality, FIG. 11 here shows only one actuator device, but it is understood that a multiplicity of actuator devices can be present, each of which is able to be controlled individually by open-loop and/or closed-loop control.

The above description of exemplary embodiments, embodiments or variant embodiments should be understood to be by way of example. The disclosure effected thereby firstly enables a person skilled in the art to understand the present disclosure and the advantages associated therewith, and secondly encompasses alterations and modifications of the described structures and methods that are also obvious in the understanding of a person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Projection exposure apparatus
12 Exposure radiation source
14 Exposure radiation
16 Illumination optics unit
18 Mask
20 Mask displacement stage
22 Projection lens
24 Substrate
26 Substrate displacement stage
28 Exposure beam path
30-1, 30-2, 30-3, 30-4, 30-5, 30-6, 30-7, 30-8 Mirror elements
32 Active optical surface
34 Support element
36, 36-1 Actuator
38 Adaptive optical module
40 Control device
42 Control signal
42-1 Displacement
42-1S Target displacement
44 Wavefront measuring device
46 Wavefront deviations
48 Dielectric medium
50 Active volume
52 Inactive volume
54 Electrode
54a Driving electrodes
54b Base electrodes
55 Electrode arrangement
56 Wiring
82 Equivalent circuit diagram
84 Capacitor of the actuator
86 Internal parallel resistor
90 Suitable frequency range
92 Cutoff frequency
94 Unsuitable frequency range
100 Comparison module
102 Correction
138 Adaptive optical module
158 Voltage generator
160 Operating voltage
161 Actuator voltage
164 Measuring capacitor
165 Ohmic resistance
166 Reference characteristic
168 Control unit
170 Control mode
172 Conversion formula
174 Calibration mode
176 Voltage measuring unit
178 Voltage drop across the measuring capacitor
180 Ohmic resistance
188 Electric charge of the actuator
196 Evaluation device
198 Dependence of displacement on the operating voltage
162 Measuring device
238 Adaptive optical module
262 Measuring device
263 Operational amplifier
264 Capacitor
267 Current intensity
338 Adaptive optical module
362 Measuring device
363 Operational amplifier
365 Measuring resistor
366 Smoothing capacitor
369 Current intensity measuring module
371 Summation module
438 Adaptive optical module
462 Measuring device
465 Shunt resistor
469 Current intensity measuring module
476 Voltmeter
479 Voltage amplifiers
481 Operational amplifier
483 First resistor
485 Second resistor
487 Smoothing capacitor
538 Adaptive optical module
566 Reference characteristic
568 Control unit
572 Conversion formula
591 Operational amplifier
593 PID controller
594 Manipulated variable
596 Feedback circuit
597 Target value for the voltage U_{M}
610 Projection exposure apparatus
612 Exposure radiation source
614 Exposure radiation
616 Beam-shaping and illumination system
618 Photomask
622 Projection lens
623 Optical axis
624 Substrate
626 Substrate displacement stage
630 Optical element
630-1, 630-4, 630-5 Lens element
630-2 Adaptive optical module
630-3 Mirror
631 Liquid medium
632 Active optical mirror surface

What is claimed is:

1. An adaptive optical module, comprising:
an actuator, comprising: a dielectric medium; and electrodes configured to provide an electric field in the dielectric medium to deform the dielectric medium to modify an optical surface of the optical module;
a measuring device, comprising: a measuring capacitor; and a voltage measuring unit, the measuring device configured to determine an electric charge located on the electrodes based on a voltage measurement of the voltage measuring unit at the measuring capacitor; and
a processing device configured to use the determined electric charge to determine a quantity relating to a displacement of the actuator,
wherein the quantity relating to the displacement of the actuator represents a dependence of the displacement of the actuator on an operating voltage of the adaptive optical module.

2. The adaptive optical module of claim 1, wherein the processing device is configured to determine the displacement of the actuator based on the determined electric charge.

3. The adaptive optical module of claim 1, wherein the processing device comprises a feedback circuit configured to keep a determined electric charge at a target value.

4. The adaptive optical module of claim 1, wherein the measuring device comprises an ohmic resistor connected in parallel with the electrodes.

5. The adaptive optical module of claim 1, wherein the measuring device comprises an ohmic resistor connected in parallel with the measuring capacitor.

6. The adaptive optical module of claim 1, wherein the measuring device comprises:
a first ohmic resistor connected in parallel with the electrodes; and
a second ohmic resistor connected in parallel with the measuring capacitor.

7. The adaptive optical module of claim 6, wherein the processing device is configured to determine the displacement of the actuator based on the determined electric charge.

8. The adaptive optical module of claim 6, wherein the processing device comprises a feedback circuit configured to keep a determined electric charge at a target value.

9. The adaptive optical module of claim 1, wherein a capacitance of the measuring capacitor is at least one order of magnitude greater than a capacitance of the actuator.

10. The adaptive optical module of claim 1, wherein the measuring device comprises a Sawyer-Tower circuit.

11. An apparatus, comprising:
an adaptive optical module according to claim 1,
wherein the apparatus is a microlithographic projection exposure apparatus.

12. An adaptive optical module, comprising:
an actuator, comprising: a dielectric medium; and electrodes configured to provide an electric field in the dielectric medium to deform the dielectric medium to modify an optical surface of the optical module;
a measuring device, comprising: an operational amplifier; and a voltage measuring unit, the measuring device configured to determine an electric charge located on the electrodes based on a voltage measurement of the voltage measuring unit at an output of the operational amplifier; and
a processing device configured to use the determined electric charge to determine a quantity relating to a displacement of the actuator,
wherein the quantity relating to the displacement of the actuator represents a dependence of the displacement of the actuator on an operating voltage of the adaptive optical module.

13. The adaptive optical module of claim 12, wherein the measuring device further comprises a measuring capacitor.

14. An apparatus, comprising:
an adaptive optical module according to claim 12,
wherein the apparatus is a microlithographic projection exposure apparatus.

15. An adaptive optical module, comprising:
an actuator, comprising: a dielectric medium deformable by an electric field in the dielectric medium; and electrodes configured to provide the electric field in the dielectric medium when a working voltage is applied thereto so that the actuator modifies an optical surface of the optical module;
a measuring device comprising: a current intensity measuring module configured to measure a current intensity of a current flowing to the electrodes when the working voltage is applied to the electrodes; and a summation module configured to determine the electric charge on the electrodes by summing the current intensities measured at different times; and
a processing device configured to use the determined electric charge to determine a quantity relating to a displacement of the actuator,
wherein the quantity relating to the displacement of the actuator represents a dependence of the displacement of the actuator on an operating voltage of the adaptive optical module.

16. The adaptive optical module of claim 15, wherein the current intensity measuring module comprises a transimpedance amplifier.

17. The adaptive optical module of claim 15, wherein the current intensity measuring module comprises a shunt resistor and a voltmeter configured to measure a voltage drop across the shunt resistor.

18. The adaptive optical module of claim 17, wherein the voltmeter comprises a voltage amplifier.

19. An apparatus, comprising:
an adaptive optical module according to claim 15,
wherein the apparatus is a microlithographic projection exposure apparatus.

20. A method of determining a displacement of an actuator of an adaptive optical module of a microlithographic projection exposure apparatus, the comprising a dielectric medium and electrodes, the method comprising:
applying a working voltage to the electrodes to generate an electric field in the dielectric medium;
measuring an electric charge located on the electrodes when the working voltage is applied;
using the charge measurement to determine a quantity relating to the displacement of the actuator,
wherein the quantity relating to the displacement of the actuator represents a dependence of the displacement of the actuator on an operating voltage of the adaptive optical module.
